(19) United States
(12) Patent Application Publication
(10) Pub. No.: US 2024/0348017 A1
(43) Pub. Date: Oct. 17, 2024

(54) LASER COMPONENT AND LASER DEVICE

(71) Applicants: ams-OSRAM International GmbH, Regensburg (DE); ams-OSRAM Asia Pacific Pte. Ltd., Singapore (SG)

(72) Inventors: Jörg Erich SORG, Regensburg (DE); Stefan BERNHARD, Graz (AT)

(73) Assignees: ams-OSRAM International GmbH, Regensburg (DE); ams-OSRAM Asia Pacific Pte. Ltd., Singapore (SG)

(21) Appl. No.: 18/682,213

(22) PCT Filed: Aug. 5, 2022
(86) PCT No.: PCT/SG2022/050561

§ 371 Date: Feb. 8, 2024

(30) Foreign Application Priority Data
Aug. 10, 2021 (DE) 10 2021 120 778.9

(51) Int. Cl. H01S 5/40

(52) U.S. Cl. CPC H01S 5/4043; H01S 5/4087

(57) ABSTRACT

A laser component is provided, the laser component including at least one first laser diode, and at least one second laser diode, the first laser diode and the second laser diode each including an active zone in a semiconductor layer, the active zones each extend parallel to the main plane of extension of the respective laser diode, the semiconductor layers each include a first side and a second side facing away from the first side, the first side and the second side each extending parallel to the main plane of extension of the respective laser diode, the second laser diode being arranged on the first laser diode in a vertical direction which is perpendicular to the main plane of extensions of the laser diodes, the first laser diode having a larger extent in its main plane of extension than the second laser diode in its main plane of extension and at least one electrical contact is arranged in a contact region of the first laser diode which is arranged on the side of the first laser diode facing the second laser diode. A laser device is also disclosed.

### CROSS-REFERENCE TO RELATED APPLICATIONS

The present application is a national stage entry from International Application No. PCT/SG2022/050561, filed on Aug. 5, 2022, published as International Publication No. WO 2023/018371 A1 on Feb. 16, 2023, and claims priority to German Patent Application No. 10 2021 120 778.9, filed Aug. 10, 2021, the disclosures of all of which are hereby incorporated by reference in their entireties.

### FIELD

A laser component and a laser device are provided.

### BACKGROUND

Lasers are used for a variety of applications such as projection systems, distance measurements or spectroscopy. Thereby it is often necessary to use several lasers or laser chips. For mobile or particularly small applications, there is the additional requirement of a compact and at the same time precise arrangement of the lasers.

A task to be solved is to provide a laser component with a compact structure. Another task to be solved is to provide a laser device with a compact structure.

### SUMMARY

According to at least one embodiment of the laser component, the laser component comprises at least one first laser diode and at least one second laser diode. The first laser diode may comprise a structure that is different from the structure of the second laser diode. The first laser diode has a main plane of extension. The second laser diode has a main plane of extension. The main plane of extension of the first laser diode is parallel to the main plane of extension of the second laser diode. The first laser diode and the second laser diode may each be a laser chip, in particular a semiconductor laser chip. The first laser diode and the second laser diode are each configured to generate laser radiation during operation.

According to at least one embodiment of the laser component, the first laser diode and the second laser diode each comprise an active zone in a semiconductor layer. That means, the first laser diode comprises a semiconductor layer in which an active zone is arranged. The second laser diode also comprises a semiconductor layer in which an active zone is arranged. The semiconductor layers can each comprise an n-doped region and a p-doped region, with the active zone being arranged between the n-doped region and the p-doped region. In this case, the p-doped regions are each doped with at least one p-dopant, and the n-doped regions are each doped with at least one n-dopant. The active zones are each configured to generate laser radiation during operation of the respective laser diode.

According to at least one embodiment of the laser component, the active zones each extend parallel to the main plane of extension of the respective laser diode. That means, the active zone of the first laser diode extends parallel to the main plane of extension of the first laser diode. In a plane which is parallel to the main plane of extension of the first laser diode, the active zone of the first laser diode may have the shape of a rectangle or strip. The first laser diode may be an edge-emitting laser diode. The active zone of the second laser diode extends parallel to the main plane of extension of the second laser diode. In a plane parallel to the main plane of extension of the second laser diode, the active zone of the second laser diode may have the shape of a rectangle or stripe. The second laser diode may be an edge-emitting laser diode.

According to at least one embodiment of the laser component, the semiconductor layers each have a first side and a second side facing away from the first side, the first side and the second side each extending parallel to the main plane of extension of the respective laser diode. That is, the semiconductor layer of the first laser diode comprises a first side and a second side facing away from the first side, the first side and the second side each extending parallel to the main plane of extension of the first laser diode. Thus, the first side and the second side of the semiconductor layer of the first laser diode are arranged on opposite sides of the semiconductor layer. The semiconductor layer of the second laser diode comprises a first side and a second side opposite to the first side, the first side and the second side each extending parallel to the main plane of extension of the second laser diode. Thus, the first side and the second side of the semiconductor layer of the second laser diode are arranged on opposite sides of the semiconductor layer.

According to at least one embodiment of the laser component, the second laser diode is arranged on the first laser diode in a vertical direction that runs perpendicular to the main plane of extensions of the laser diodes. The vertical direction runs perpendicular to the main plane of extension of the first laser diode and perpendicular to the main plane of extension of the second laser diode. Thus, the first laser diode and the second laser diode are arranged one above the other in the vertical direction. The second laser diode may be arranged entirely on the first laser diode. This may mean that the second laser diode does not exceed the first laser diode in a plane parallel to the main plane of extension of the first laser diode. The first laser diode may be flush with the second laser diode on at least one side. The second laser diode may be in direct contact with the first laser diode.

According to at least one embodiment of the laser component, the first laser diode has a larger extent in its main plane of extension than the second laser diode in its main plane of extension. This may mean that the area over which the first laser diode extends in its main plane of extension is larger than the area over which the second laser diode extends in its main plane of extension. The first laser diode may have the shape of a rectangle in its main plane of extension. The second laser diode can have the shape of a rectangle in its main plane of extension.

According to at least one embodiment of the laser component, at least one electrical contact is arranged in a contact region of the first laser diode, which is arranged on the side of the first laser diode facing the second laser diode. The electrical contact may comprise an electrically conductive material. The contact region may be arranged on an upper side of the first laser diode. The electrical contact can be connected with the first laser diode. There can be an electrically conductive connection between the electrical contact and the first laser diode, in particular between the electrical contact and the active zone of the first laser diode. The first laser diode can be configured to be provided with power via the electrical contact. The laser component can be free of an electrically conductive connection between the electrical contact and the active zone of the second laser diode.

According to at least one embodiment of the laser component, the laser component comprises at least one first laser diode and at least one second laser diode, the first laser diode and the second laser diode each comprising an active zone in a semiconductor layer, the active zones each extending parallel to the main plane of extension of the respective laser diode, the semiconductor layers each comprising a first side and a second side facing away from the first side, the first side and the second side each extending parallel to the main plane of extension of the respective laser diode, characterized in that the second laser diode is arranged on the first laser diode in a vertical direction which runs perpendicular to the main plane of extensions of the laser diodes, the first laser diode has a larger extent in its main plane of extension than the second laser diode in its main plane of extension, and at least one electrical contact is arranged in a contact region of the first laser diode which is arranged on the side of the first laser diode which faces the second laser diode.

The laser component described here is based, inter alia, on the idea that a compact arrangement is made possible. This is achieved, for example, by the first laser diode and the second laser diode being arranged one above the other. Furthermore, the first laser diode has a greater extent than the second laser diode, so that the contact region is arranged on the upper side of the first laser diode. The contact region can be used for electrical contacting of both the first laser diode and the second laser diode. The contact region can be used for electrical contacting of both the first laser diode and the second laser diode independently. This also contributes to a compact arrangement of the laser component. Since the laser component has at least two laser diodes in total, namely the first laser diode and the second laser diode, it is possible for the laser component to emit laser radiation of at least two different wavelengths during operation.

Furthermore, the arrangement of the laser component can be achieved with a high degree of precision. Thus, the first laser diode and the second laser diode can be in direct contact with each other. That is, no carrier or other component increasing the distance between the two laser diodes is arranged between the first laser diode and the second laser diode. This structure of the laser component allows the first laser diode and the second laser diode to be arranged with a high precision relative to each other. Therefore, the areas where the laser radiation emerges from the two laser diodes during operation are also arranged with a high precision relative to each other.

According to at least one embodiment of the laser component, the laser component comprises a third laser diode. The third laser diode comprises an active zone in a semiconductor layer. The active zone of the third laser component extends parallel to the main plane of extension of the third laser diode. The third laser diode may be arranged in a vertical direction on the second laser diode. Thus, the second laser diode may be arranged in vertical direction between the first laser diode and the third laser diode. Advantageously, with a third laser diode, it is possible for the laser component to emit laser radiation at three different wavelengths during operation. Thus, the wavelength of the laser radiation emitted by the third laser diode in operation can be different from the wavelengths of the laser radiation emitted by the first laser diode and the second laser diode.

According to at least one embodiment of the laser component, the laser component comprises a fourth laser diode. The fourth laser diode comprises an active zone in a semiconductor layer. The active zone of the fourth laser component extends parallel to the main plane of extension of the fourth laser diode. The fourth laser diode may be arranged in a vertical direction on the third laser diode. Thereby, the third laser diode may be arranged adjacent to the first laser diode. Thus, the fourth laser diode is arranged adjacent to the second laser diode. With a third and a fourth laser diode, it is advantageously possible for the laser component to emit laser radiation with four different wavelengths during operation. Thus, the wavelength of the laser radiation emitted by the fourth laser diode in operation can be different from the wavelengths of the laser radiation emitted by the other three laser diodes.

According to at least one embodiment of the laser component, the laser component comprises a total of more than three laser diodes. This enables the laser component to emit laser radiation of different wavelengths during operation, wherein the laser component can have a compact structure overall. The various laser diodes of the laser component can be arranged one above the other and/or side by side.

According to at least one embodiment of the laser component, both active zones are respectively arranged closer to the second side than to the first side of the respective semiconductor layer and the second side of the semiconductor layer of the first laser diode faces the second side of the semiconductor layer of the second laser diode. That is, the active zone of the first laser diode is arranged closer to the second side of the semiconductor layer of the first laser diode than to the first side of the semiconductor layer of the first laser diode. The active zone of the second laser diode is arranged closer to the second side of the semiconductor layer of the second laser diode than to the first side of the semiconductor layer of the second laser diode. This can be achieved, for example, by epitaxially growing each of the semiconductor layers on a substrate. In a region facing away from the substrate, the n-dopants and the p-dopants are introduced. Thus, the active zone is formed between the p-doped region and the n-doped region. In this case, the region of the semiconductor layer facing the substrate is less doped or not doped at all. The substrate is then removed. This leaves a semiconductor layer with the substrate removed on the first side and with the n-doped region, the p-doped region and the active zone arranged closer to the second side than to the first side.

That the second side of the semiconductor layer of the first laser diode faces the second side of the semiconductor layer of the second laser diode may mean that the second side of the semiconductor layer of the first laser diode is arranged closer to the second laser diode than the first side of the semiconductor layer of the first laser diode. Also, the second side of the semiconductor layer of the second laser diode is arranged closer to the first laser diode than the first side of the semiconductor layer of the second laser diode. Thus, both the second side of the semiconductor layer of the first laser diode and the second side of the semiconductor layer of the second laser diode face a junction plane between the first laser diode and the second laser diode. On the one hand, this structure enables the area from which laser radiation is emitted during operation of the first laser diode and the area from which laser radiation is emitted during operation of the second laser diode to be close to each other. This is achieved by the fact that for both semiconductor layers the active zone is located closer to the second side than to the first side and that the two second sides face each other. Furthermore, this structure enables a further electrical contact to be arranged in the contact region, via which the second laser diode can be electrically contacted at the second side of the semiconductor layer. For this purpose, an electrically conductive connection can be arranged between the two semiconductor layers in order to electrically connect the semiconductor layer of the second laser diode to the further electrical contact. Overall, this results in a compact arrangement of the laser component.

According to at least one embodiment of the laser component, the semiconductor layers comprise a p-doped region at their second side or the semiconductor layers comprise an n-doped region at their second side and in both cases the second side of the semiconductor layer of the first laser diode faces the second side of the semiconductor layer of the second laser diode. If the semiconductor layers comprise a p-doped region at their second side, the semiconductor layers also comprise an n-doped region which is arranged at a distance from the second side adjacent to the p-doped region. If the semiconductor layers comprise an n-doped region on their second side, the semiconductor layers also comprise a p-doped region which is arranged at a distance from the second side adjacent to the n-doped region. As described above, this structure enables a compact arrangement of the laser component.

According to at least one embodiment of the laser component, the contact region is free of the second laser diode. This may mean that the second laser diode does not cover the contact region. Thus, the second laser diode is not arranged on the contact region. Advantageously, this allows electrical connections to be routed away from the contact region, for example to a carrier. The electrical connections may be bonding wires.

According to at least one embodiment of the laser component, the electrical contact is connected to the second side of the semiconductor layer of the first laser diode via an electrically conductive connection. For this purpose, the first laser diode may comprise an electrically conductive contact layer which is electrically conductively connected to the second side of the semiconductor layer and to the electrical contact. The contact layer can extend over the entire extent of the first laser diode parallel to its main plane of extension. Thus, advantageously, the region of the semiconductor layer of the first laser diode which is adjacent to the second side, for example the p-doped region, can be electrically contacted via the electrical contact. The region of the semiconductor layer which is arranged on the side of the active zone facing away from the second side, thus for example the n-doped region, can be electrically contacted either on the first side of the semiconductor layer or also on the second side of the semiconductor layer. The electrical contacts of the p-doped region and the n-doped region are electrically isolated from each other.

According to at least one embodiment of the laser component, a further electrical contact is arranged in the contact region, which is connected to the second side of the semiconductor layer of the second laser diode via an electrically conductive connection. For this purpose, the second laser diode can comprise an electrically conductive contact layer, which is electrically conductively connected to the second side of the semiconductor layer and to the further electrical contact. The contact layer can extend over the entire extent of the second laser diode parallel to its main plane of extension. Thus, advantageously, the region of the semiconductor layer of the second laser diode which is adjacent to the second side, for example the p-doped region, can be electrically contacted via the further electrical contact. The region of the semiconductor layer which is arranged on the side of the active zone facing away from the second side, thus for example the n-doped region, can be electrically contacted either on the first side of the semiconductor layer or also on the second side of the semiconductor layer. The electrical contacts of the p-doped region and the n-doped region are electrically isolated from each other. The further electrical contact can be connected with the second laser diode. There can be an electrically conductive connection between the further electrical contact and the second laser diode, in particular between the further electrical contact and the active zone of the second laser diode. The second laser diode can be configured to be provided with power via the further electrical contact. The laser component can be free of an electrically conductive connection between the further electrical contact and the active zone of the first laser diode.

According to at least one embodiment of the laser component, the first laser diode and the second laser diode each comprise a further active zone in their semiconductor layer, wherein in the first laser diode and in the second laser diode the further active zone each extends parallel to the active zone. That is, the first laser diode comprises the active zone and a further active zone, wherein the further active zone extends parallel to the active zone. The active zone and the further active zone may have the same size and the same structure. Further, the first laser diode may comprise the active zone and at least two further active zones. The active zone and the further active zones may be arranged parallel to each other. Further, the active zone and the further active zones may extend parallel to each other. For the active zone and the further active zones, the regions from which the generated laser radiation exits the first laser diode may be arranged on the same side of the first laser diode. Further, the second laser diode comprises the active zone and a further active zone, wherein the further active zone extends parallel to the active zone. The active zone and the further active zone may have the same size and structure. Further, the second laser diode may comprise the active zone and at least two further active zones. The active zone and the further active zones may be arranged parallel to each other. Further, the active zone and the further active zones may extend parallel to each other. For the active zone and the further active zones, the regions from which the generated laser radiation exits the second laser diode may be arranged on the same side of the second laser diode. The laser component can thus comprise a plurality of active zones overall, and thus a plurality of zones from which laser radiation is emitted during operation. The active zones and the further active zones can be configured to be provided with power separately, respectively. This can mean that each active zone and each further active zone is connected with its own electrical contact or further electrical contact. Advantageously, the areas from which laser radiation is emitted during operation are arranged compactly adjacent to one another. In addition, the areas from which laser radiation is emitted during operation can be precisely positioned relative to one another, on the one hand by arranging a plurality of active zones within a laser diode, which enables precise positioning, and on the other hand by arranging the second laser diode on the first laser diode, wherein the two second sides face one another.

According to at least one embodiment of the laser component, the first laser diode comprises an electrically insulation layer on its side facing the second laser diode and the second laser diode comprises a further electrically insulation layer on its side facing the first laser diode. The electrically insulation layers each comprise an electrically insulating material. Advantageously, the electrically insulation layers enable the electrical contact to be electrically insulated from the further electrical contact. This enables to electrically contact the first laser diode independently from the second laser diode. Furthermore, the electrically insulation layers electrically insulate the contact layer of the first laser diode from the contact layer of the second laser diode.

According to at least one embodiment of the laser component, the electrically insulation layer and the further electrically insulation layer each comprise a via which extends in the vertical direction and is at least partially filled with an electrically conductive material. The vias may be recesses that are at least partially filled with the electrically conductive material. The electrically conductive material of the vias of the first laser diode may be in direct contact with the electrical contact and with the contact layer of the first laser diode. The electrically conductive material of the via of the second laser diode can be in direct contact with the further electrical contact and with the contact layer of the second laser diode. This enables the semiconductor layer of the first laser diode to be electrically contactable via the electrical contact and the semiconductor layer of the second laser diode to be electrically contactable via the further electrical contact.

According to at least one embodiment of the laser component, the first laser diode comprises a first mirror and a second mirror, wherein the first mirror has a distance to the second mirror and wherein the distance is smaller than the extent of the first laser diode parallel to a connection axis between the first mirror and the second mirror. The connection axis between the first mirror and the second mirror may be parallel to the main plane of extension of the first laser diode. Along this connection axis, the first laser diode has an extent that is greater than the distance between the first mirror and the second mirror along this connection axis. The first mirror may be arranged on an outer side of the first laser diode. The second mirror may be arranged entirely within the first laser diode. The second mirror may have a greater reflectivity than the first mirror, particularly for the wavelength of laser radiation generated in the active zone during operation. The second mirror may be formed in such a way that, prior to the deposition of the second mirror, a region of the semiconductor layer is removed by etching. Thus, the active zone, which is used to generate laser radiation, may be located entirely below the second laser diode. This means that the active zone, which is used to generate laser radiation, is arranged exclusively in the part of the first laser diode that is covered by the second laser diode. The semiconductor layer arranged below the contact region is not used for generating laser radiation. Thus, the contact region can be used for electrical contacting. Since the second mirror can be arranged entirely within the first laser diode, the length of the active region can be chosen to have different values. The active region does not necessarily have the length of the whole extension of the first laser diode but can be shorter.

According to at least one embodiment of the laser component, the first laser diode is configured to emit, in operation, laser radiation of a first wavelength at a side that is transverse or perpendicular to the main plane of extension of the first laser diode, and the second laser diode is configured to emit, in operation, laser radiation of a second wavelength at a side that is transverse or perpendicular to the main plane of extension of the second laser diode. The side at which laser radiation is emitted at the first laser diode in operation and the side at which laser radiation is emitted by the second laser diode in operation may be arranged at the same side of the laser component. Thus, the first laser diode and the second laser diode can be configured to emit laser radiation in the same direction during operation. If the laser component has more than two laser diodes, all laser diodes of the laser component may be adapted to emit laser radiation in the same direction during operation. The first wavelength and the second wavelength may be the same. With the structure described here, a compact arrangement of the areas from which laser radiation is emitted is achieved.

According to at least one embodiment of the laser component, the first wavelength is different from the second wavelength. Thus, the laser component can advantageously emit laser radiation of different wavelengths or colors. If the laser component comprises a third laser diode, the third laser diode may be configured to emit laser radiation of a third wavelength during operation. The third wavelength may be different from the first wavelength and the second wavelength.

According to at least one embodiment of the laser component, the difference between the first wavelength and the second wavelength is at most 5 nm. This means that the first wavelength and the second wavelength differ by at most 5 nm.

According to at least one embodiment of the laser component, the first wavelength and the second wavelength are identical.

A laser device is further disclosed. The laser device comprises the laser component described herein. Thus, all features disclosed for the laser component are also disclosed for the laser device.

According to at least one embodiment of the laser device, the laser device comprises the laser component and a carrier, wherein the laser component is arranged on the carrier. The carrier may be a submount or the carrier may comprise a mounting element. The carrier has a main plane of extension that is parallel to the main plane of extension of the first laser diode and to the main plane of extension of the second laser diode. The carrier may comprise at least one recess in which electrically conductive material is arranged. That is, the carrier may have at least one via. Thus, the carrier can have at least one electrical contact on the side facing away from the laser component. Thus, the carrier may be surface mountable. The carrier may comprise aluminum nitride. Since the laser component has a compact structure, the laser device also has a compact structure overall.

According to at least one embodiment of the laser device, the carrier comprises an integrated circuit and the side of the carrier facing away from the laser component forms a bottom side of the laser device. The carrier may be, for example, a connection carrier, a circuit board, a printed circuit board, or a wafer. The carrier may comprise or consist of a semiconductor material. For example, the carrier may be formed by silicon onto which and/or into which electrically conductive structures such as conductor tracks and/or contact points are applied and/or introduced. The first laser diode and the second laser diode may be electrically connected to the integrated circuit. The integrated circuit may be configured to electrically drive the first laser diode and the second laser diode. No other component of the laser device is arranged on the side of the carrier facing away from the laser component. Thus, the carrier forms a bottom plate of the laser device. This means that the carrier with the integrated circuit advantageously simultaneously enables the control of the two laser diodes and forms the bottom plate of the laser device. Thus, no further bottom plate is required for the laser device. Therefore, the laser device can have a compact structure. Furthermore, by avoiding another bottom plate, inaccuracies in alignment or assembly are avoided, so that the laser component can be precisely positioned on the carrier.

According to at least one embodiment of the laser device, the laser device comprises an encapsulation enclosing the laser component. The encapsulation may be arranged on the carrier. The encapsulation may comprise sidewalls arranged on the carrier and surrounding the laser component. The sidewalls may extend transversely or perpendicularly to the main plane of extension of the carrier. The sidewalls may be translucent at least in places. The sidewalls may be at least locally translucent to laser radiation emitted by the laser component during operation. A cover may be arranged on the sidewalls on the side of the laser component facing away from the carrier. The cover may be spaced apart from the laser component. The cover may be translucent at least in places. The cover may be translucent, at least in places, to laser radiation emitted by the laser component during operation. The laser component is completely enclosed by the carrier and the encapsulation. This means that the laser component is not in direct contact with the environment outside the encapsulation and the carrier. Thus, the laser component is protected from external environmental influences. This increases the service life of the laser component.

According to at least one embodiment of the laser device, a leakage rate of air to the laser component is at most 5*10⁻⁸ mbar*liter/second. This may mean that the leakage rate of air through the encapsulation, the carrier and the connection between the encapsulation and the carrier is at most 5*10⁻⁸ mbar*liter/second. Thus, the laser device is hermetically sealed. In this case, the carrier and the encapsulation form a hermetically sealed arrangement in which the laser component is arranged. In other words, the carrier and the encapsulation form a hermetically sealed cavity in which the laser component is arranged. Thus, the laser component is protected from external environmental influences. This increases the service life of the laser component.

According to at least one embodiment of the laser device, the electrical contact is electrically connected to at least one portion of the carrier. The electrical contact of the first laser diode may be electrically connected to an electrical contact of the integrated circuit of the carrier. Thus, the first laser diode can be electrically driven by the carrier. The further electrical contact may also be electrically connected to at least one portion of the carrier. Thus, the further electrical contact of the second laser diode may be electrically connected to an electrical contact of the integrated circuit of the carrier. Thus, the second laser diode may also be electrically driven by the carrier.

A further laser device is disclosed. The further laser device comprised at least one laser diode which is arranged on a carrier. The carrier comprises an integrated circuit and the side of the carrier facing away from the laser diode forms a bottom side of the further laser device. Thus, the carrier forms a bottom plate of the further laser device. Further, the further laser device comprises an encapsulation on the carrier surrounding the laser diode. The components of the further laser device may comprise the features described in connection with the laser device. Instead of the laser diode, the further laser component may comprise a laser component described herein.

In the following, the laser component and the laser device described herein are explained in more detail in connection with embodiments and the accompanying figures.

### BRIEF DESCRIPTION OF THE DRAWINGS

FIG. 1 shows a schematic cross-section through a laser component according to an embodiment.

FIG. 2 shows a schematic cross-section through a second laser diode according to an embodiment.

FIGS. 3 and 4 show schematic cross-sections through a laser device according to an embodiment.

FIGS. 5 and 6 show top views of a laser component according to an embodiment.

FIG. 7 shows a top view of a second laser diode according to an embodiment.

FIG. 8 shows a top view of a laser component according to a further embodiment.

FIG. 9 shows a top view of a second laser diode according to a further embodiment.

FIGS. 10 and 11 describe another embodiment of a laser device.

### DETAILED DESCRIPTION

Elements that are identical, similar or have the same effect are given the same reference signs in the figures. The figures and the proportions of the elements shown in the figures are not to be regarded as to scale. Rather, individual elements may be shown exaggeratedly large for better representability and/or for better comprehensibility.

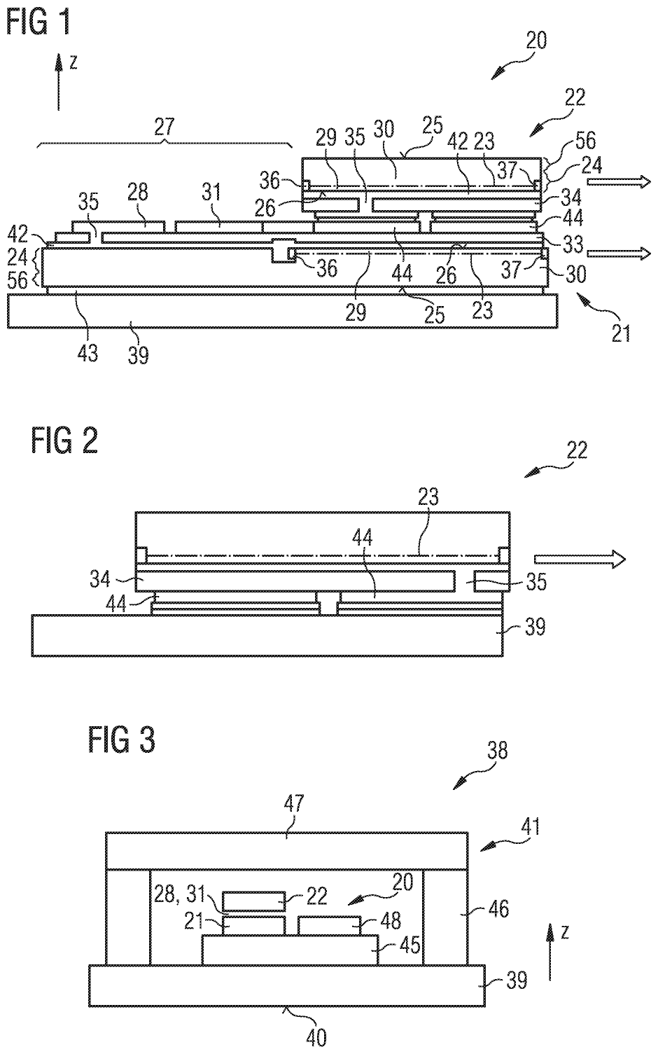

FIG. 1 shows a schematic cross-sectional view of a laser component 20 according to an embodiment. The laser component 20 comprises a first laser diode 21 and a second laser diode 22. The second laser diode 22 is arranged on the first laser diode 21 in a vertical direction z, which is perpendicular to the main plane of extensions of the two laser diodes 21, 22. The first laser diode 21 may be arranged on a carrier 39. In this case, the carrier 39 is not necessarily part of the laser component 20. The first laser diode 21 is thus arranged in the vertical direction z between the carrier 39 and the second laser diode 22.

The first laser diode 21 and the second laser diode 22 each comprise a semiconductor layer 24, wherein an active zone 23 is arranged in each semiconductor layer 24. The active zones 23 each extend parallel to the main plane of extension of the respective laser diode 21, 22. The semiconductor layers 24 each comprise a first side 25 and a second side 26 facing away from the first side 25. The first side 25 and the second side 26 each extend parallel to the main plane of extension of the respective laser diode 21, 22. The semiconductor layers 24 further each comprise a p-doped region 29 and an n-doped region 30. The active zone 23 is arranged in the vertical direction z between the p-doped region 29 and the n-doped region 30 in each case.

The semiconductor layers 24 may each be arranged on a substrate 56 or a support layer 56. In each case, the n-doped region 30 faces the substrate 56 or the support layer 56. The support layer 56 may comprise a metal.

The two active zones 23 are each arranged closer to the second side 26 than to the first side 25 of the respective semiconductor layer 24. Furthermore, for both semiconductor layers 24, the p-doped region 29 is arranged at the second side 26. Thus, for both semiconductor layers 24, the p-doped region 29 is arranged closer to the second side 26 than the n-doped region 30.

The second side 26 of the semiconductor layer 24 of the first laser diode 21 faces the second side 26 of the semiconductor layer 24 of the second laser diode 22. Thus, the two n-doped regions 30 are farther apart than the two p-doped regions 29.

The first laser diode 21 comprises a first mirror 36 and a second mirror 37. The active zone 23 is arranged between the first mirror 36 and the second mirror 37. Thus, the first mirror 36 and the second mirror 37 form the resonator of the first laser diode 21. The first mirror 36 has a distance from the second mirror 37, the distance being smaller than an extent of the first laser diode 21 parallel to a connecting axis between the first mirror 36 and the second mirror 37. Thus, the active zone 23 does not extend over the entire extent of the first laser diode 21 parallel to the main extension direction of the active zone 23. The active zone 23 of the first laser diode 21 is arranged only in the region over which the second laser diode 22 is arranged.

The second laser diode 22 also comprises a first mirror 36 and a second mirror 37. The active zone 23 is arranged between the first mirror 36 and the second mirror 37. Thus, the first mirror 36 and the second mirror 37 form the resonator of the second laser diode 22. The first mirror 36 and the second mirror 37 of the second laser diode 22 are each adjacent to an outer surface of the second laser diode 22. Thus, the active zone 23 of the second laser diode 22 extends over the entire extent of the second laser diode 22 parallel to the main extension direction of the active zone 23.

The first laser diode 21 is configured to emit, in operation, laser radiation of a first wavelength on a side that is perpendicular to the main plane of extension of the first laser diode 21. The laser radiation generated during operation of the first laser diode 21 may exit the first laser diode 21 from the second mirror 37. Thus, the second mirror 37 is an exit mirror. The direction of propagation of the exiting laser radiation is perpendicular to the vertical direction z, which is shown with an arrow in FIG. 1.

The second laser diode 22 is configured to emit, in operation, laser radiation of a second wavelength on a side that is perpendicular to the main plane of extension of the second laser diode 22. The laser radiation generated during operation of the second laser diode 22 may exit the second laser diode 22 from the second mirror 37. Thus, the second mirror 37 is an exit mirror. The direction of propagation of the exiting laser radiation is perpendicular to the vertical direction z, which is shown with an arrow in FIG. 1.

The first wavelength may be different from the second wavelength, such that the laser component 20 is adapted to emit laser radiation of different wavelengths.

The first laser diode 21 has a larger extent in its main plane of extension than the second laser diode 22 in its main plane of extension. Thus, a contact region 27 remains on the side of the first laser diode 21 facing the second laser diode 22, which is free of the second laser diode 22. An electrical contact 28 is arranged in the contact region 27.

The electrical contact 28 is connected to the second side 26 of the semiconductor layer 24 of the first laser diode 21 via an electrically conductive connection. For this purpose, the first laser diode 21 comprises an electrically insulation layer 33 on its side facing the second laser diode 22. The electrically insulation layer 33 comprises a via 35 which extends in the vertical direction z and which is filled with an electrically conductive material. The via 35 is arranged adjacent to the electrical contact 28. In the vertical direction z, the via 35 is arranged below the electrical contact 28. An electrically conductive contact layer 42 of the first laser diode 21 extends parallel to the electrically insulation layer 33. The contact layer 42 is in direct contact with the electrically conductive material in the via 35. The contact layer 42 extends over the entire extent of the first laser diode 21 in its main plane of extension. In the vertical direction z, the contact layer 42 is arranged below the electrically insulation layer 33. Furthermore, in the vertical direction z, the contact layer 42 is arranged on the semiconductor layer 24. At the second side 26 of the semiconductor layer 24, the contact layer 42 is in direct contact with the semiconductor layer 24 and thus with the p-doped region 29. This means that the p-doped region 29 is electrically conductively connected to the electrical contact 28. A further contact layer 43 is arranged on the first side 25 of the semiconductor layer 24. The further contact layer 43 is also electrically conductive. Thus, the n-doped region 30 of the semiconductor layer 24 is electrically contacted via the further contact layer 43. The further contact layer 43 may be in direct contact with an electrical contact of the carrier 39.

A further electrical contact 31 is arranged in the contact region 27. The further electrical contact 31 is connected to the second side 26 of the semiconductor layer 24 of the second laser diode 22 via an electrically conductive connection. The second laser diode 22 comprises at least two connection regions 44. The connection regions 44 are electrically conductive at least in places. Each of the connection regions 44 comprises three superimposed layers, which are electrically conductive. In addition, the second laser diode 22 comprises a further electrically insulation layer 34 on its side facing the first laser diode 21. The connection regions 44 are arranged in vertical direction z below the further electrically insulation layer 34. The connection region 44 shown on the left side in FIG. 1 is electrically conductively connected to the further electrical contact 31. This is done via an electrically conductive contact bar 51, which is not shown in the cross-section. The further electrically insulation layer 34 has a via 35 which extends in the vertical direction z and which is filled with an electrically conductive material. The via 35 is arranged adjacent to one of the connection regions 44. In the vertical direction z, the via 35 is arranged above the connection region 44. This is the connection region 44, which is shown on the left in FIG. 1. An electrically conductive contact layer 42 of the second laser diode 22 extends parallel to the further electrically insulation layer 34. The contact layer 42 is in direct contact with the electrically conductive material in the via 35. The contact layer 42 extends over the entire extent of the second laser diode 22 in its main plane of extension. In the vertical direction z, the contact layer 42 is arranged above the electrically insulation layer 33. Further, in the vertical direction z, the contact layer 42 is arranged below the semiconductor layer 24. At the second side 26 of the semiconductor layer 24, the contact layer 42 is in direct contact with the semiconductor layer 24 and thus with the p-doped region 29. This means that the p-doped region 29 is electrically conductively connected to the further electrical contact 31.

A further contact layer 43 may be arranged on the first side 25 of the semiconductor layer 24, which is not shown in FIG. 1. The further contact layer 43 is also electrically conductive. Thus, the n-doped region 30 of the semiconductor layer 24 can be electrically contacted via the further contact layer 43. The further contact layer 43 can be electrically connected to a portion of the carrier 39 or a portion of the contact region 27 via a bond wire 55.

FIG. 2 shows a schematic cross-section through the second laser diode 22 according to an embodiment. The second laser diode 22 is arranged on a carrier 39, which is not part of the second laser diode 22. The second laser diode 22 has the structure shown in FIG. 1 with the only difference that the via 35 is arranged above the right connection region 44 instead of above the left connection region 44.

FIG. 3 shows a schematic cross-sectional view of a laser device 38 according to an embodiment. The laser device 38 comprises the laser component 20 and a carrier 39. The laser component 20 is arranged on the carrier 39. For this purpose, the laser component 20 is arranged on a mounting element 45 and the mounting element 45 is arranged on the carrier 39. The laser component 20 comprises the first laser diode 21, the second laser diode 22, and a third laser diode 48. Thereby, the second laser diode 22 is arranged on the first laser diode 21 in vertical direction z. The third laser diode 48 is arranged on the mounting element 45 adjacent to the first laser diode 21. The third laser diode 48 may be configured to emit laser radiation of a third wavelength. The third wavelength may be different from the first wavelength and the second wavelength.

The carrier 39 comprises an integrated circuit. The mounting element 45 can have vias. Thus, the electrical contact 28 and the further electrical contact 31 can be electrically connected to the carrier 39 via the mounting element 45. It is further possible for the mounting element 45 to comprise electrically conductive layers connected to the vias. The mounting element 45 may comprise aluminum nitride, silicon or silicon carbide. Further, the mounting element 45 may also comprise an integrated circuit. In this case, the integrated circuit of the mounting element 45 and the integrated circuit of the carrier 39 are electrically connected to each other.

The side of the carrier 39 that faces away from the laser component 20 forms a bottom side 40 of the laser device 38.

The laser device 38 further comprises an encapsulation 41 arranged on the carrier 39 and enclosing the laser component 20. The encapsulation 41 comprises sidewalls 46 that are arranged on the carrier 39 and surround the laser component 20. On the side of the laser component 20 facing away from the carrier 39, a cover 47 is arranged on the sidewalls 46. A leakage rate into this arrangement of the carrier 39 and the encapsulation 41 is at most 5*10⁻⁸ mbar*liter/second. Thus, a leakage rate from air to the laser component 20 is at most 5*10⁻⁸ mbar*liter/second.

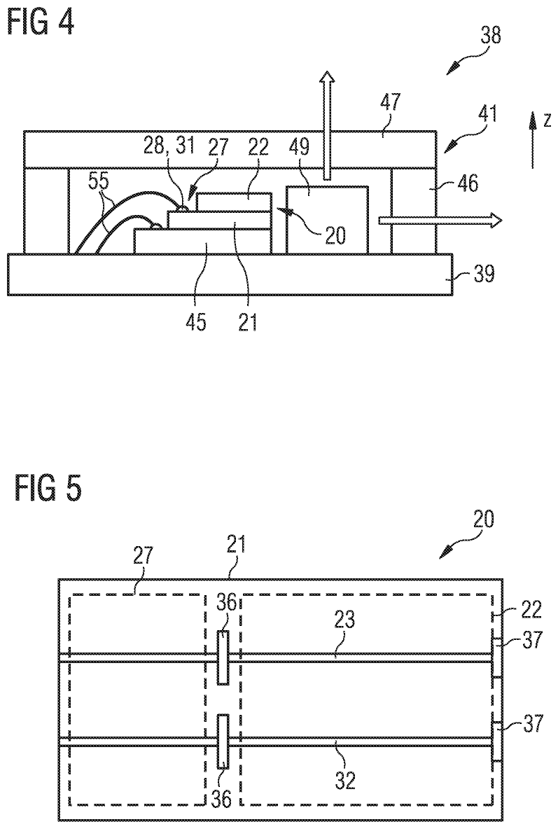

FIG. 4 shows another cross-section through the laser device 38 of FIG. 3. The plane in which the cross-section of FIG. 3 is located encloses an angle of 90° with the plane in which the cross-section of FIG. 4 is located. Thus, a view of a different side of the laser device 38 is shown in FIG. 4 than in FIG. 3.

The electrical contact 28, which is arranged in the contact region 27, is electrically connected to the carrier 39 via a bond wire 55. The further electrical contact 31 can also be electrically connected to the carrier 39 via a bond wire 55. An electrical contact, which is arranged on the side of the mounting element 45 that faces away from the carrier 39, is electrically connected to the carrier 39 via a bond wire 55. This electrical contact of the mounting element 45 may be electrically connected to the n-doped region 30 of the first laser diode 21.

An optical element 49 is disposed on the carrier 39 and within the encapsulation 41 adjacent the laser component 20. The optical element 49 may serve for beam shaping or beam directing of laser radiation emitted from the laser component 20. Thus, laser radiation can exit the optical element 49 in the vertical direction z or in a direction which is perpendicular to the vertical direction z. This is shown by arrows in FIG. 4.

FIG. 5 shows a top view of the laser component 20 according to an embodiment. The outer boundary line indicates the shape of the first laser diode 21. Dotted lines indicate the shape of the second laser diode 22 and the contact region 27. In this embodiment, the first laser diode 21 has the active zone 23 and a further active zone 32. The further active zone 32 extends parallel to the active zone 23, and the further active zone 32 may have the same structure as the active zone 23. The active zone 23 and the further active zone 32 are spaced apart from each other. The further active zone 32 is also arranged between a first mirror 36 and a second mirror 37. The second laser diode 22 may also have a further active zone 32 in the same manner.

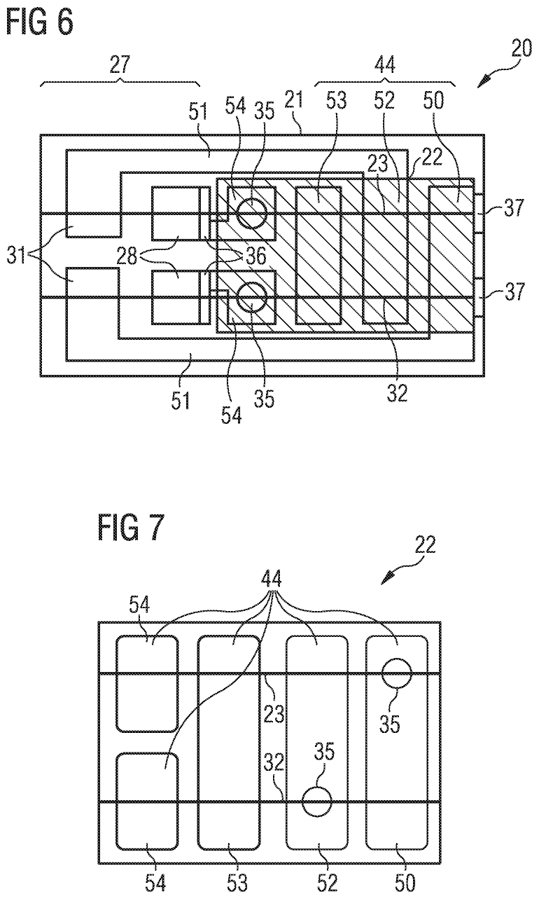

FIG. 6 shows another top view of the laser component 20 according to an embodiment. Here, other areas of the laser component 20 are shown than in FIG. 5. The outer boundary line indicates the shape of the first laser diode 21. The shape of the second laser diode 22 is shaded. Also shown are the active zone 23 and the further active zone 32 of the first laser diode 21 with the first mirrors 36 and the second mirrors 37.

Above the first laser diode 21, the connection region 44 of the second laser diode 22 are arranged. The connection regions 44 are arranged spaced apart from each other. The connection regions 44 extend in places in a direction which, in the top view, is perpendicular to the main extension direction of the active zones 23. A first connection region 50 is arranged above the side of the first laser diode 21 where the second mirrors 37 are arranged. The first connection region 50 is electrically connected to the further electrical contact 31 via a contact bar 51. In this embodiment, the laser component 20 has a total of two further electrical contacts 31. These are arranged on the opposite side compared to the first connection region 50. Thus, the contact bar 51 extends over the entire extent of the first laser diode 21. A second connection region 52 is arranged at a distance from the first connection region 50 and closer to the first mirrors 36 than the first connection region 50. The second connection region 52 is also electrically connected to the other of the two further electrical contacts 31 via a contact bar 51. A third connection region 53 is spaced apart from the second connection region 52 and is arranged closer to the first mirrors 36 than the second connection region 52. Furthermore, a fourth connection region 54 is arranged adjacent to the third connection region 53. The fourth connection region 54 is divided into two separate parts. The fourth connection region 54 is arranged spaced apart from the third connection region 53. The third connection region 53 and the fourth connection region 54 are not electrically connected to the further electrical contact 31, nor to the semiconductor layer 24. Thus, the third connection region 53 and the fourth connection region 54 serve to dissipate heat for the second laser diode 22.

Adjacent to the first mirrors 36, two vias 35 are disposed in the electrically insulation layer 33 above the semiconductor layer 24. The electrically conductive material in each of the vias 35 is electrically connected to one of the two electrical contacts 28. The two electrical contacts 28 and the two further electrical contacts 31 are arranged in the contact region 27.

FIG. 7 shows a top view of a cross-section through the second laser diode 22 according to an embodiment. The second laser diode 22 comprises the active zone 23 and a further active zone 32, which is arranged parallel to the active zone 23. Thereby, the first connection region 50, the second connection region 52 and the third connection region 53 are shown, which are arranged next to each other as in FIG. 6. In addition, the fourth connection region 54 is arranged adjacent to the third connection region 53. The first connection region 50 is electrically conductively connected to the electrically conductive material in a via 35 in the further electrically insulation layer 34. The second connection region 52 is also electrically conductively connected to the electrically conductive material in a further via 35 in the further electrically insulation layer 34. The third connection region 53 and the fourth connection region 54 are not electrically connected to the further electrical contact 31, nor to the semiconductor layer 24. Thus, the third connection region 53 and the fourth connection region 54 serve to dissipate heat for the second laser diode 22. The fourth connection region 54 comprises an interruption in a region between the active zone 23 and the further active zone 32. Thus, the fourth connection region 54 is divided into two separate parts. This prevents electrical short circuits in underlying areas.

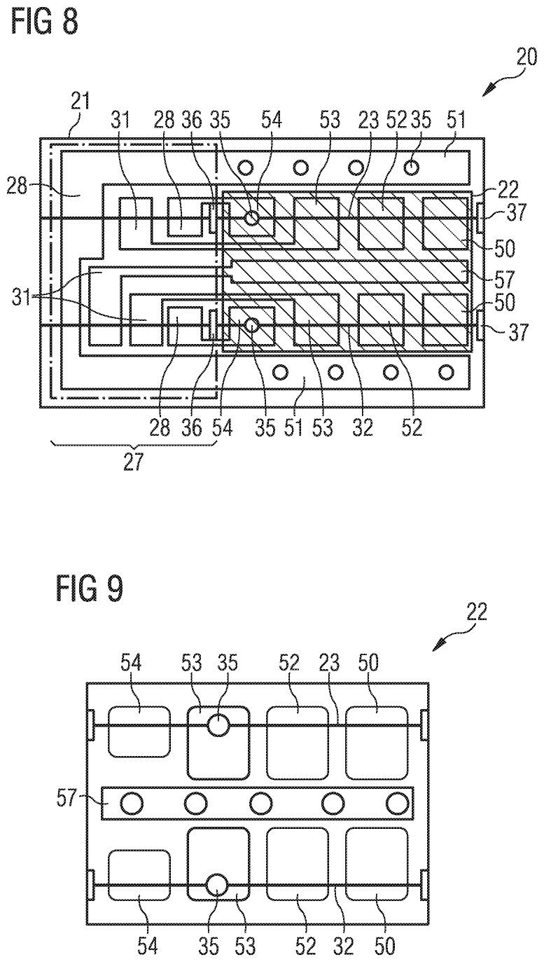

FIG. 8 shows a top view of the laser component 20 according to another embodiment. The laser component 20 is shown similar to FIG. 6. The outer boundary line indicates the shape of the first laser diode 21. The shape of the second laser diode 22 is shaded. Also shown are the active zone 23 and the further active zone 32 of the first laser diode 21 with the first mirrors 36 and the second mirrors 37.

The first laser diode 21 comprises vias 35 through the semiconductor layer 24. The vias 35 through the semiconductor layer 24 are electrically conductively connected to the n-doped region 30 of the first laser diode 21. The vias 35 through the semiconductor layer 24 are arranged below an area which is free of the second laser diode 22 and which is not the contact region 27. On the side of the first laser diode 21 facing the second laser diode 22, two contact bars 51 are arranged, each of which electrically connects some of the vias 35 through the semiconductor layer 24 to an electrical contact 28. The electrical contact 28 is arranged in the contact region 27. An electrical contact 28 is also arranged in the contact region 27, which is electrically connected to the p-doped region 29 above the active zone 23 of the first laser diode 21 via a via 35. Furthermore, an electrical contact 28 is arranged in the contact region 27, which is electrically connected to the p-doped region 29 above the further active zone 32 of the first laser diode 21 via a via 35.

The second laser diode 22 comprises two first connection regions 50, two second connection regions 52, two third connection regions 53, two fourth connection regions 54, and one fifth connection region 57. One of the third connection regions 53 is electrically conductively connected to the p-doped region 29 below the active zone 23 of the second laser diode 22. This third connection region 53 is electrically connected to another electrical contact 31 in the contact region 27. The other of the third connection regions 53 is electrically conductively connected to the p-doped region 29 below the further active zone 32 of the second laser diode 22. This third connection region 53 is electrically connected to a further electrical contact 31 in the contact region 27. The fifth connection region 57 is electrically conductively connected to the n-doped region 30 of the second laser diode 22. The fifth connection region 57 is electrically connected to another electrical contact 31 in the contact region 27. Thus, a total of three electrical contacts 28 and three further electrical contacts 31 are arranged in the contact region 27.

FIG. 9 shows a top view of a cross-section through the second laser diode 22 according to another embodiment. The second laser diode 22 may be the second laser diode 22 of the embodiment of the laser component 20 shown in FIG. 8. In this case, the second laser diode 22 is similar to that shown in FIG. 7. The fifth connection region 57 is spaced apart from the other connection regions 50, 52, 53, 54. Thereby, the fifth connection region 57 extends parallel to the main extension direction of the active zone 23 and the main extension direction of the further active zone 32. The fifth connection region 57 is arranged respectively between the two first connection regions 50, between the two second connection regions 52, between the two third connection regions 53 and between the two fourth connection regions 54. A via 35 is arranged above each of the third connection regions 53. Via these vias 35, the third connection regions 53 are electrically conductively connected to the p-doped region 29 of the second laser diode 22. Vias 35 are arranged above the fifth connection region 57, via which the fifth connection region 57 is electrically conductively connected to the n-doped region 30 of the second laser diode 22. The third connection regions 53 and the fifth connection regions 57 thus serve for electrical contacting, for mechanical connection of the second laser diode 22 to the first laser diode 21 and for heat dissipation. The remaining connection regions 50, 52, 54 serve for mechanical connection of the second laser diode 22 with the first laser diode 21 and for heat dissipation.

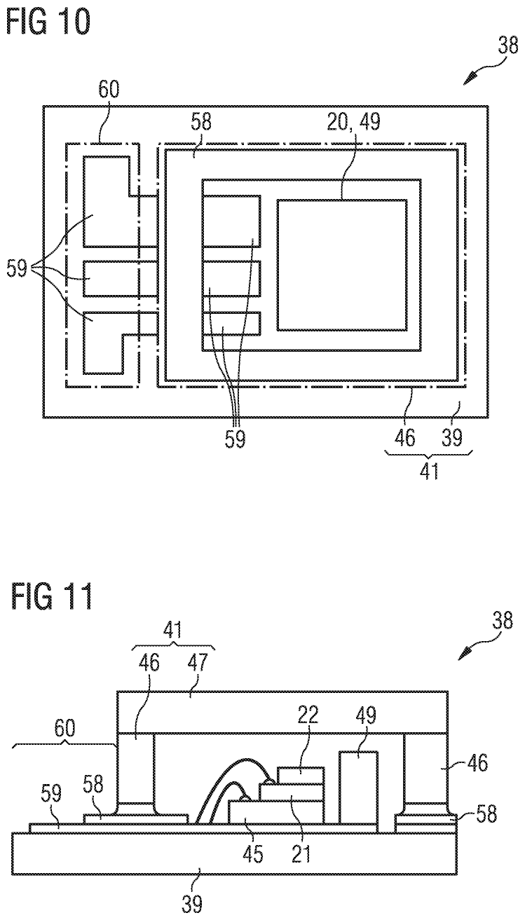

FIG. 10 shows a top view of another embodiment of laser device 38. The laser device 38 comprises the laser component 20 and the optical element 49. The top view in FIG. 10 shows the surface on which the laser component 20 and the optical element 49 are mounted. The laser component 20, the optical element 49, and side walls 46 of an encapsulation 41 are arranged on the carrier 39. In addition, an insulation layer 58 is arranged on the carrier 39 to surround the laser component 20 and the optical element 49 in a frame-like manner. The insulation layer 58 is arranged within the sidewalls 46 and below the sidewalls 46. Connection layers 59 are arranged between the insulation layer 58 and the carrier 39. The connection layers 59 are electrically conductive. Three connection layers 59 are shown by way of example in FIG. 10. The connection layers 59 extend on the carrier 39 below the insulation layer 58 through out of the encapsulation 41. In an access region 60 on the carrier 39 adjacent to the encapsulation 41, the connection layers 59 are exposed for electrical contacting. The connection layers 59 may be electrically connected to the first laser diode 21 and the second laser diode 22. Thus, the first laser diode 21 and the second laser diode 22 can be electrically contacted via the connection layers 59. Advantageously, the connection layers 59 are thereby partially outside the encapsulation 41. By passing the connection layers 59 between the sidewalls 46 and the carrier 39, the laser component 20 can be further hermetically sealed. The isolation layer 58 prevents a short circuit across the sidewalls 46.

FIG. 11 shows a schematic cross-section through the embodiment of the laser device 38 shown in FIG. 10. The first laser diode 21 and the second laser diode 22 are arranged on the mounting element 45 on the carrier 39. In addition to the first laser diode 21 and the second laser diode 22, the optical element 49 is arranged on the carrier 39. Sidewalls 46 on the carrier 39 and the cover 47 on the sidewalls 46 form the encapsulation 41. Connection layers 59 are arranged on the carrier 39, and the insulation layer 58 is arranged between the sidewalls 46 and the connection layers 59. The connection layers 59 can be electrically contacted in the access region 60 outside the encapsulation 41.

The features and embodiments described in connection with the figures can be combined with each other according to further embodiments, even if not all combinations are explicitly described. Furthermore, the embodiments described in connection with the figures may alternatively or additionally have further features according to the description in the general part.

The invention is not limited by the description based on the embodiments to said embodiments. Rather, the invention encompasses any new feature as well as any combination of features, which in particular includes any combination of features in the patent claims, even if this feature or combination itself is not explicitly stated in the patent claims or embodiments.

1. A laser component comprising:
at least one first laser diode, and
at least one second laser diode, wherein
the first laser diode and the second laser diode each comprise an active zone in a semiconductor layer,
the active zones each extend parallel to the main plane of extension of the respective laser diode,
the semiconductor layers each comprise a first side and a second side facing away from the first side, the first side and the second side each extending parallel to the main plane of extension of the respective laser diode,
the second laser diode is arranged on the first laser diode in a vertical direction which runs perpendicular to the main plane of extensions of the laser diodes,
the first laser diode has a larger extent in its main plane of extension than the second laser diode in its main plane of extension, and
at least one electrical contact is arranged in a contact region of the first laser diode, which is arranged on the side of the first laser diode facing the second laser diode.

2. The laser component according to the previous claim 1, wherein both active zones are each arranged closer to the second side than to the first side of the respective semiconductor layer, and wherein the second side of the semiconductor layer of the first laser diode faces the second side of the semiconductor layer of the second laser diode.

3. The laser component according to claim 1, wherein the semiconductor layers comprise a p-doped region on their second side or the semiconductor layers comprise an n-doped region on their second side, and wherein in both cases the second side of the semiconductor layer of the first laser diode faces the second side of the semiconductor layer of the second laser diode.

4. The laser component according to claim 1, wherein the contact region is free of the second laser diode.

5. The laser component according to claim 1, wherein the electrical contact is connected to the second side of the semiconductor layer of the first laser diode via an electrically conductive connection.

6. The laser component according to claim 1, wherein in the contact region a further electrical contact is arranged, which is connected to the second side of the semiconductor layer of the second laser diode via an electrically conductive connection.

7. (canceled)

8. The laser component according to claim 1, wherein the first laser diode comprises an electrically insulation layer on its side facing the second laser diode and the second laser diode comprises a further electrically insulation layer on its side facing the first laser diode.

9. The laser component according to claim 8, wherein the electrically insulation layer and the further electrically insulation layer each comprise a via which extends in the vertical direction and is at least partially filled with an electrically conductive material.

10. The laser component according to claim 1, wherein the first laser diode comprises a first mirror and a second mirror, wherein the first mirror has a distance to the second mirror, and wherein the distance is less than an extent of the first laser diode parallel to a connection axis between the first mirror and the second mirror.

11. The laser component according to claim 10, wherein the second mirror is arranged entirely within the first laser diode.

12. The laser component according to claim 1, wherein the first laser diode is configured to emit, in operation, laser radiation of a first wavelength at a side which is transverse or perpendicular to the main plane of extension of the first laser diode, and the second laser diode is configured to emit, in operation, laser radiation of a second wavelength at a side which is transverse or perpendicular to the main plane of extension of the second laser diode.

13. The laser component according to claim 12, wherein the first wavelength is different from the second wavelength.

14. The laser component according to claim 13, wherein the difference between the first wavelength and the second wavelength is at most 5 nm.

15. The laser component according to claim 12, wherein the first wavelength and the second wavelength are identical.

16. A laser device comprising the laser component according to claim 1 and a carrier, wherein the laser component is arranged on the carrier.

17. The laser device according to claim 16, wherein the carrier comprises an integrated circuit and the side of the carrier facing away from the laser component forms a bottom side of the laser device.

18. The laser device according to claim 16, wherein the laser device comprises an encapsulation enclosing the laser component.

19. The laser device according to claim 18, wherein a leakage rate of air to the laser component is at most 5*10⁻⁸ mbar*liter/second.

20. The laser device according to claim 16, wherein the electrical contact is electrically connected to at least one portion of the carrier.

21. A laser component comprising:
at least one first laser diode; and
at least one second laser diode, wherein
the first laser diode and the second laser diode each comprise an active zone in a semiconductor layer,
the active zones each extend parallel to the main plane of extension of the respective laser diode,
the first laser diode and the second laser diode each comprise a further active zone in their semiconductor layer, wherein in the first laser diode and in the second laser diode the further active zone each extends parallel to the active zone,
the semiconductor layers each comprise a first side and a second side facing away from the first side, the first side and the second side each extending parallel to the main plane of extension of the respective laser diode,
the second laser diode is arranged on the first laser diode in a vertical direction which runs perpendicular to the main plane of extensions of the laser diodes,
the first laser diode has a larger extent in its main plane of extension than the second laser diode in its main plane of extension,
at least one electrical contact is arranged in a contact region of the first laser diode, which is arranged on the side of the first laser diode facing the second laser diode,
the contact region is used for electrical contacting of the first laser diode and the second laser diode independently, and
each active zone and each further active zone is connected with its own electrical contact or a further electrical contact.
